(19) United States
(12) Patent Application Publication
(10) Pub. No.: US 2026/0333560 A1
(43) Pub. Date: Oct. 22, 2026

(54) PLASMA GENERATION APPARATUS AND METHOD USING ELECTRON BEAM

(71) Applicant: IUCF-HYU (INDUSTRY-UNIVERSITY COOPERATION FOUNDATION HANYANG UNIVERSITY), Seoul (KR)

(72) Inventors: Chin Wook CHUNG, Seoul (KR); Min Seok KIM, Seoul (KR); Ji Won JUNG, Seoul (KR); Jun Young PARK, Seoul (KR)

(21) Appl. No.: 19/651,548

(22) Filed: Apr. 17, 2026

Related U.S. Application Data
(63) Continuation of application No. PCT/KR2024/015931, filed on Oct. 18, 2024.

(30) Foreign Application Priority Data
Oct. 20, 2023 (KR) 10-2023-0141505

(51) Int. Cl. H05H 1/24

(52) U.S. Cl. CPC H05H 1/24

(57) ABSTRACT

A plasma generation apparatus using an electron beam according to an embodiment of the disclosed invention may include a first chamber configured to define a space in which plasma is generated and to receive a first gas through a first gas inlet, a second chamber disposed below the first chamber and configured to receive a second gas through a second gas inlet, and a grid unit disposed between the first chamber and the second chamber.

### CROSS-REFERENCE TO RELATED APPLICATION

This application is a bypass continuation of pending PCT International Application No. PCT/KR2024/015931, which was filed on Oct. 18, 2024, and which claims priority from Korean Patent Application No. 10-2023-0141505, filed on Oct. 20, 2023, the disclosure of which is incorporated herein by reference in its entirety.

### BACKGROUND

### 1. Field of the Invention

The present invention relates to a plasma generation apparatus and method using an electron beam, and more particularly, to an invention capable of generating radicals under specific conditions in a second chamber through an electron beam generated from plasma in a first chamber while gases are respectively introduced into the first chamber and the second chamber.

### 2. Discussion of Related Art

Plasma is an ionized gas composed of positive ions, negative ions, electrons, excited atoms, molecules, and chemically highly reactive radicals, and is also referred to as a fourth state of matter because it has electrical and thermal characteristics that are significantly different from those of an ordinary gas. Because such plasma includes ionized gas, it is very useful in semiconductor manufacturing processes, for example, for accelerating species by using an electric field or a magnetic field or for inducing chemical reactions to clean, etch, or deposit on a wafer or substrate.

Recently, semiconductor manufacturing processes have employed plasma generation apparatuses capable of generating high-density plasma, and various plasma modules are used to generate plasma, representative examples being capacitive coupled plasma (CCP) using radio frequency and inductively coupled plasma (ICP).

For example, an inductively coupled plasma (ICP) generation apparatus is an apparatus for generating high-density plasma, in which a process gas is introduced into a chamber in which plasma is generated, and high-frequency power is applied through a high-frequency antenna disposed near a dielectric window formed at an upper portion of the chamber, thereby forming an induced electric field in the chamber through the dielectric window.

The induced electric field thus formed ionizes the process gas to generate plasma inductively coupled with the antenna. Such plasma is used to clean, etch, or deposit on objects such as a semiconductor wafer or substrate mounted on a lower electrode.

However, in a conventional plasma-enhanced chemical vapor deposition (PECVD) scheme, plasma is generated after reaction materials are introduced in a gaseous state and RF power is applied. Because such plasma includes a large number of high-energy electrons, indiscriminate radical-generation reactions occur, resulting in the formation of undesired reaction products.

In addition, in the conventional plasma-enhanced chemical vapor deposition (PECVD) scheme, film quality at a substrate is poor and step coverage is low.

### SUMMARY

Accordingly, an apparatus and method for generating plasma using an electron beam according to an embodiment of the disclosed invention has been made to solve the above-described problems, and an object thereof is to provide a technique in which gases are respectively introduced into a first chamber and a second chamber, an electron beam is generated from plasma in the first chamber and applied to the second chamber, and an ultra-low-electron-temperature plasma including specific radicals is generated in the second chamber and deposited on a substrate.

Another object of an apparatus and method for generating plasma using an electron beam according to an embodiment is to selectively generate radical active species required for deposition by controlling the energy of the electron beam through a grid unit.

According to an embodiment of the disclosed invention, a plasma generation apparatus using an electron beam may include: a first chamber configured to define a space in which plasma is generated and to receive a first gas through a first gas inlet; a second chamber disposed below the first chamber and configured to receive a second gas through a second gas inlet; and a grid unit disposed between the first chamber and the second chamber.

The apparatus may further include a grid voltage controller configured to apply a voltage to the grid unit so as to adjust sheath potential energy formed at the grid unit.

The apparatus may further include a controller configured to control the type of radical generated from the second gas in the second chamber by adjusting the voltage applied by the grid voltage controller.

A supply flow rate of the first gas may be at least twice a supply flow rate of the second gas.

In the plasma generation apparatus using an electron beam, plasma may be generated from the first gas in the first chamber, and an electron beam may be generated in the second chamber from the plasma that has passed through the grid unit.

In the plasma generation apparatus using an electron beam, an ultra-low-electron-temperature plasma including a specific radical may be generated from the second gas in the second chamber by using energy of the electron beam.

The plasma generation apparatus using an electron beam may further include a substrate disposed below the second chamber so that the radical included in the ultra-low-electron-temperature plasma is adsorbed thereon.

The second gas inlet may be disposed between a lower layer of the grid unit and the substrate and may be positioned closer to the grid unit.

The first gas and the second gas may be different types of gases.

According to an embodiment of the disclosed invention, a plasma generation method using an electron beam may include: introducing a first gas into a first chamber; applying an induced electric field through an antenna disposed at one side of the first chamber and generating high-density plasma from the first gas using the applied induced electric field; introducing a second gas into a second chamber disposed below the first chamber; and applying a voltage to a grid unit disposed between the first chamber and the second chamber.

The applying of the voltage to the grid unit may further include adjusting, by the controller, the voltage applied by the grid voltage controller according to a type of radical to be generated from the second gas in the second chamber.

The plasma generation method using an electron beam may further include generating an electron beam in the second chamber from the plasma through the grid unit.

A supply flow rate of the first gas may be at least twice a supply flow rate of the second gas.

The plasma generation method using an electron beam may further include depositing the radical on a substrate disposed below the second chamber.

According to an embodiment of the disclosed invention, a plasma generation apparatus using an electron beam may include: a first chamber configured to define a space in which plasma is generated and to receive a first gas through a first gas inlet; an antenna connected to a power source, disposed at one side of the first chamber, and configured to generate an induced electric field and supply the induced electric field to the first chamber; a second chamber disposed below the first chamber and configured to receive a second gas through a second gas inlet; and a grid unit disposed between the first chamber and the second chamber and configured to allow the first gas to pass into the second chamber, wherein an ultra-low-electron-temperature plasma including a specific radical is generated from the second gas in the second chamber by using energy of an electron beam generated from the first gas through the grid unit.

### Advantageous Effects

According to an embodiment of the disclosed invention, the plasma generation apparatus and method using an electron beam have an advantage in that gases are respectively introduced into the first chamber and the second chamber, primary plasma is generated in the first chamber, an electron beam is generated from the primary plasma, and an ultra-low-electron-temperature plasma including radicals can be generated in the second chamber through the electron beam, so that radicals required for deposition can be obtained at high density.

In addition, an apparatus and method for generating plasma using an electron beam according to an embodiment have an advantage in that radical active species required for deposition can be selectively generated by controlling, through the grid unit, energy of the electron beam required for radical generation.

In addition, an apparatus and method for generating plasma using an electron beam according to an embodiment have an advantage in that additional decomposition of radicals used for deposition can be minimized, thereby securing high process yield.

In addition, an apparatus and method for generating plasma using an electron beam according to an embodiment have an advantage in that, without changing the structure of existing equipment, radicals can be generated by using the electron beam and the ultra-low-electron-temperature plasma so as to minimize substrate damage, thereby enabling a high-purity deposition process.

### BRIEF DESCRIPTION OF THE DRAWINGS

FIG. 1 is a view schematically illustrating a concept of plasma generation in the plasma generation apparatus and method using an electron beam according to an embodiment of the disclosed invention.

FIG. 2 is a view illustrating a process in which plasma is generated by an electron beam that has passed through a grid unit in the plasma generation apparatus and method using an electron beam according to an embodiment of the disclosed invention.

FIG. 3 is a graph showing a change in potential energy while plasma in a first chamber passes through a grid unit in the plasma generation apparatus and method using an electron beam according to an embodiment of the disclosed invention.

FIG. 4 is a view illustrating a plasma generation apparatus using an electron beam according to an embodiment of the disclosed invention.

FIG. 5 is a view showing electron-beam energy generated according to grid voltage in the plasma generation apparatus of FIG. 4.

FIG. 6 is a view showing electron-beam energy required according to radical active species generated through dissociation reaction of CF4 molecules in the plasma generation apparatus of FIG. 4.

FIG. 7 is a view showing radical density of F atoms according to electron-beam energy based on the graph shown in FIG. 6.

FIG. 8 is a view illustrating a plasma generation apparatus using an electron beam according to another embodiment of the disclosed invention.

FIG. 9 is a view showing electron-beam energy generated according to grid voltage in the plasma generation apparatus of FIG. 8.

FIG. 10 is a view showing electron-beam energy required according to radical active species generated through dissociation reaction of N2 molecules in the plasma generation apparatus of FIG. 8.

FIG. 11 is a view showing radical density of N atoms according to electron-beam energy based on the graph shown in FIG. 10.

FIG. 12 is a view illustrating a partial configuration of the plasma generation apparatus according to an embodiment of the disclosed invention.

FIG. 13 is a view illustrating a plasma generation method according to an embodiment of the disclosed invention.

### DETAILED DESCRIPTION OF EXEMPLARY EMBODIMENTS

The embodiments described in this specification and configurations shown in the drawings are merely preferred examples of the disclosed invention, and various modifications capable of replacing the embodiments and drawings of this specification may exist at the time of filing of the present application.

In addition, the same reference numerals or symbols shown in the respective drawings of this specification denote parts or components that perform substantially the same functions.

Further, the terminology used in this specification is for describing the embodiments and is not intended to limit and/or restrict the disclosed invention. Singular expressions include plural expressions unless the context clearly indicates otherwise.

In this specification, terms such as “include” or “have” are intended to specify the presence of stated features, numerals, steps, operations, components, parts, or combinations thereof described in the specification, and are not intended to preclude in advance the presence or addition of one or more other features, numerals, steps, operations, components, parts, or combinations thereof.

Further, terms including ordinals such as “first” and “second” used in this specification may be used to describe various components, but such components are not limited by those terms, and the terms are used only for the purpose of distinguishing one component from another component.

For example, without departing from the scope of the present invention, a first component may be referred to as a second component, and similarly a second component may be referred to as a first component. The term “and/or” includes combinations of a plurality of related listed items or any one of the plurality of related listed items.

Hereinafter, embodiments according to the present invention will be described in detail with reference to the accompanying drawings.

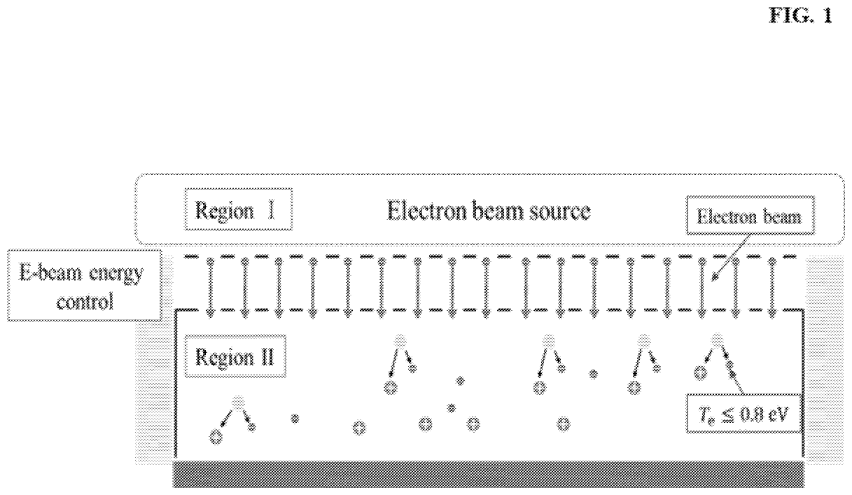

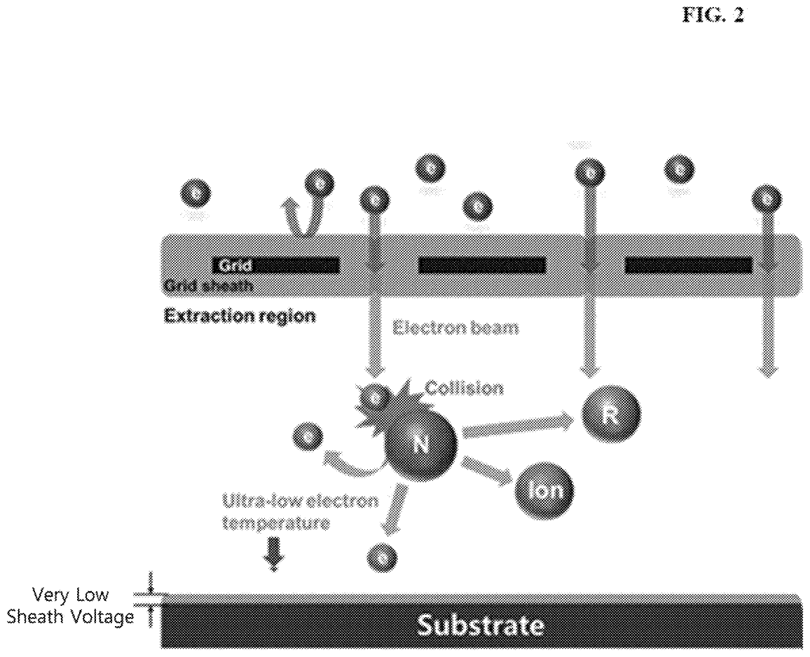

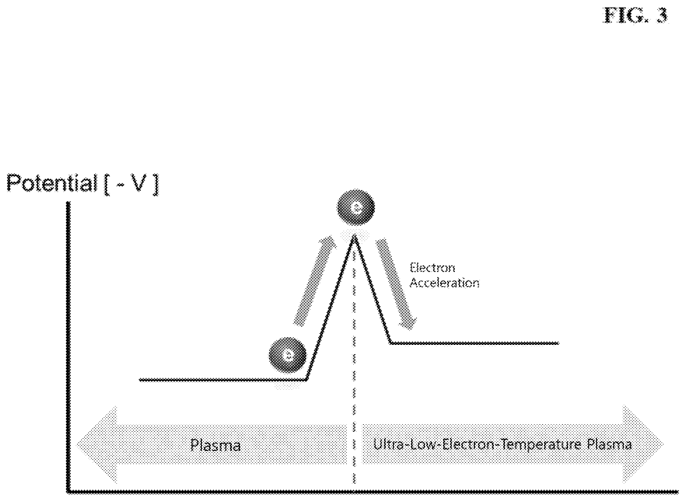

FIG. 1 is a view schematically illustrating a concept of plasma generation in the plasma generation apparatus and method using an electron beam according to an embodiment of the disclosed invention. FIG. 2 is a view illustrating a process in which plasma is generated by an electron beam that has passed through a grid unit in the plasma generation apparatus and method using an electron beam according to an embodiment of the disclosed invention. FIG. 3 is a graph showing a change in potential energy while plasma in the first chamber passes through the grid unit in the plasma generation apparatus and method using an electron beam according to an embodiment of the disclosed invention.

Referring to FIG. 1, the plasma generation apparatus using an electron beam according to an embodiment of the disclosed invention may generate primary plasma, which serves as a source of an electron beam, in a first region, and may generate an electron beam from the primary plasma in the first region and apply the electron beam to a second region.

Further, by the electron beam applied to the second region, gas in the second region may be converted into an ultra-low-electron-temperature plasma including specific radicals. More specifically, the plasma generation apparatus according to the disclosed invention may adjust energy of the electron beam generated from the primary plasma in the first region by controlling a voltage of a grid unit disposed between the first region and the second region.

Electrons included in the ultra-low-electron-temperature plasma generated in the second region may have kinetic energy of 1.0 eV or less.

Specifically, in plasma having such low electron kinetic energy, sheath voltage is formed at a low level, and because of the low sheath voltage, energy of accelerated ions can also be low, whereby substrate damage due to ion energy can be minimized.

Referring to FIGS. 2 and 3, the first region may be formed as a source region in which primary plasma serving as a source of the electron beam is generated, and the second region may be formed as an extraction region in which an electron beam that has overcome grid-sheath potential energy generated at the grid unit and passed therethrough is applied so that ultra-low-electron-temperature plasma is generated.

More specifically, electrons included in the plasma generated in the first region may be accelerated by sheath potential energy of the grid unit while passing through the grid unit. As a result, neutral gases contained in the second region may be ionized to discharge plasma.

For example, electrons accelerated after passing through the grid unit may collide with neutral gases in the second region, whereby the neutral gases may be dissociated into radicals, ions, and electrons, and electrons that have collided with the neutral gases may lose energy and thereby form a very low electron temperature.

Specifically, the second region may include low-energy electrons generated through ionization and electrons that were included in the high-density plasma of the first region, gained energy while moving to the second region through the grid unit, but lost energy by participating in ionization reactions. These electrons form a very low electron temperature, and such low-energy electrons may form ultra-low-electron-temperature plasma.

Accordingly, the disclosed invention can adsorb radicals included in the generated ultra-low-electron-temperature plasma onto a surface of a substrate.

For example, when the potential of the substrate is 0 V, a sheath voltage is not formed above the substrate because of the very low electron temperature, and even if formed, the sheath voltage is very low.

Accordingly, according to the disclosed invention, no electric field is formed that could accelerate charged particles such as ions or electrons included in the generated ultra-low-electron-temperature plasma toward the substrate, so that only electrically neutral radicals adhere to the substrate by diffusion, whereby an adsorption reaction may occur.

In addition, the plasma generation apparatus of the disclosed invention may apply a voltage to at least a portion of the substrate so as to accelerate at least one of electrons or ions included in the ultra-low-electron-temperature plasma and cause the same to collide with the substrate.

For example, the plasma generation apparatus of the disclosed invention may apply a bias such as an RF voltage or a DC voltage through at least a portion of the substrate. Depending on polarity of the voltage, electrons are directed toward the substrate when a positive voltage is applied, and (positive) ions are directed toward the substrate when a negative voltage is applied, and a reaction may occur in which a portion of a substrate surface bonded with adsorbed radicals is desorbed by energy possessed by the electrons or ions.

Therefore, the disclosed invention can partition the first region and the second region with the grid unit, inject gases into the first region and the second region, respectively, and control the voltage of the grid unit to generate specific radical active species for substrate deposition in the second region. Details related thereto will be described below.

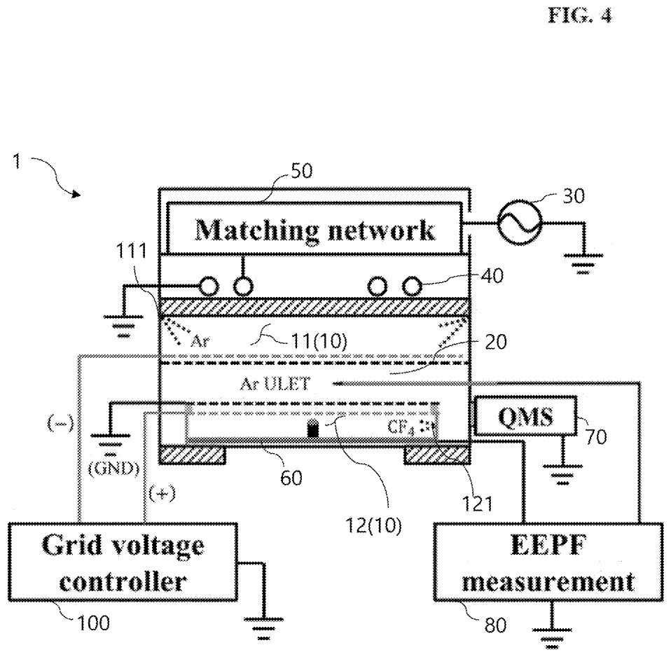

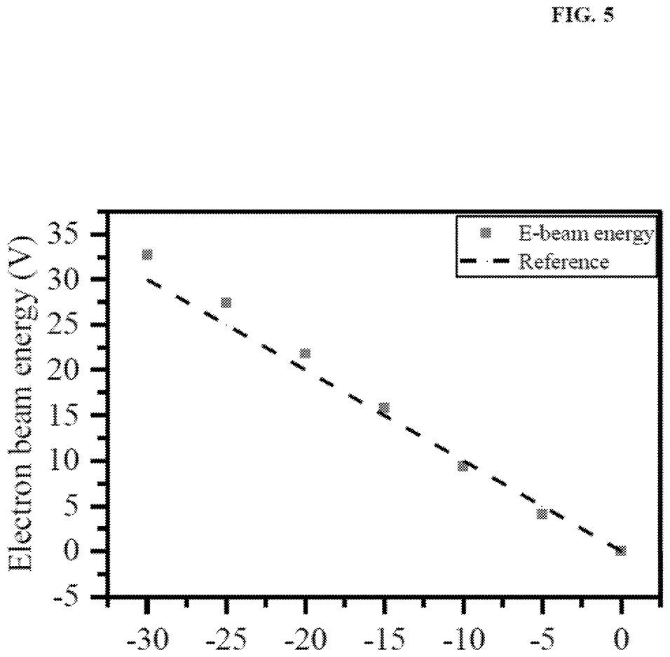

FIG. 4 is a view illustrating a plasma generation apparatus using an electron beam according to an embodiment of the disclosed invention. FIG. 5 is a view showing electron-beam energy generated according to grid voltage in the plasma generation apparatus of FIG. 4.

Referring to FIG. 4, a plasma generation apparatus (1) using an electron beam according to the disclosed invention (hereinafter referred to as the “plasma generation apparatus (1)”) may include a plurality of chambers (10) serving as a main body that defines a space in which plasma is generated, a power source (30), a plurality of antennas (40) disposed at one side of the chamber to generate plasma, an impedance matching unit (50) connected to the antennas (40) to match impedance of the antennas (40), a substrate (60) on which a plasma process is performed, a plasma measuring instrument (70) capable of measuring various parameters of plasma inside the chamber, and an electron energy probability function measuring instrument (80) for measuring energy of electrons.

The plasma generation apparatus (1) according to the disclosed invention may process the substrate (60) disposed inside the chamber by using plasma. For example, the plasma generation apparatus (1) may perform an etching process, a deposition process, an etch process, and an ion implantation process on the substrate (60) through plasma.

Further, the plasma generation apparatus (1) according to the disclosed invention may be defined as a plasma generation apparatus using various plasma generation sources, such as capacitive coupled plasma (CCP), inductively coupled plasma (ICP), an electron beam source, electron cyclotron resonance (ECR), microwave plasma, and helicon plasma.

The plurality of chambers (10) of the plasma generation apparatus (1) according to the disclosed invention may be provided as conductive material such as aluminum or stainless steel and may be configured in a grounded state. However, the plurality of chambers (10) are not limited thereto and need not be formed of a conductive material.

The plurality of chambers (10) may include a first chamber (11) and a second chamber (12).

The first chamber (11) may be configured to define a space in which plasma is generated and to receive a first gas through a first gas inlet (111).

More specifically, the first gas supplied into the first chamber (11) may be converted into plasma by an induced electric field applied by the antenna (40), which is connected to the power source (30) and generates the induced electric field. Accordingly, the first chamber (11) may define a space in which primary plasma is generated. Such primary plasma may be used as source plasma for forming an electron beam applied to the second chamber (12), which will be described later.

Accordingly, a plurality of antennas (40) for generating plasma may be installed at an upper portion of the first chamber (11), and the plurality of antennas (40) may be connected to the impedance matching unit (50). The impedance matching unit (50) is connected to the power source (30) that supplies power to the plasma generation apparatus (1), and the power source (30) may be implemented as an RF power source or a DC power source.

Here, the first gas of the first chamber (11) used in the plasma generation apparatus (1) of the disclosed invention may be argon gas.

The second chamber (12) may provide a space in which the substrate (60) is positioned and a process is performed. More specifically, the second chamber (12) is disposed below the first chamber (11) and may receive, through the second gas inlet (121), a second gas to be used for processing the substrate (60).

Here, the second gas inlet (121) may be disposed between a lower layer of the grid unit (20) and the substrate (60) and closer to the grid unit (20).

In addition, the second gas inlet (121) may be disposed at a side portion of the second chamber (12) so as to supply the second gas to the second chamber (12) without interfering with the grid unit (20).

Further, the second chamber (12) may be partitioned from the first chamber (11) by the grid unit (20) and may receive an electron beam generated from the primary plasma of the first chamber (11) to generate secondary plasma. Such secondary plasma may be referred to as ultra-low-electron-temperature plasma.

The grid unit (20) of the plasma generation apparatus (1) according to the disclosed invention may be disposed between the first chamber (11) and the second chamber (12).

More specifically, the grid unit (20) may be connected to a grid voltage controller (100). For example, the grid voltage controller (100) may apply a voltage to the grid unit (20) so as to adjust sheath potential energy formed at the grid unit (20).

In the plasma generation apparatus (1) of the disclosed invention, sheath potential energy of the grid unit is one of important physical concepts mainly used for confining and controlling ionized particles (plasma ions).

Various types of grids may be used in the plasma generation apparatus according to the disclosed invention, and such grids may be used to control movement of ions and electrons in plasma and maintain the plasma stably. In addition, the grid unit (20) may mainly confine and accelerate ions by using an electric field.

Sheath potential energy represents energy obtained by ions around the grid and is related to a voltage difference between the electric field and the grid. The sheath potential energy may be calculated as follows:

Sheath potential energy=voltage (V)×charge of ion (e)

In this region, sheath potential energy has a great influence on movement of ions, and characteristics and behavior of plasma may be determined according to how the value is adjusted. By adjusting the sheath potential energy, acceleration and confinement of ions become possible, thereby making it possible to control density, temperature, and stability of plasma.

Accordingly, a sheath voltage may be generated at the grid unit (20) of the disclosed invention, and only high-energy electrons exceeding the sheath potential energy of the grid unit (20) can move from the first chamber (11) to the second chamber (12).

Thereafter, electrons that have moved to the second chamber (12) may be amplified into high-energy electrons. The high-energy electrons with amplified electron energy may ionize neutral gases present in the second chamber (12).

In the plasma generation apparatus (1) according to an embodiment of the disclosed invention, the neutral gas corresponding to the second gas of the second chamber (12) may be implemented as CF4 gas. That is, the first gas of the first chamber (11) and the second gas of the second chamber (12) may be different types of gases.

In addition, low-energy electrons generated through ionization in the second chamber (12), together with electrons that came down from the first chamber (11) to below the grid unit (20) while gaining energy but lost energy by participating in ionization reactions, form a very low electron temperature, and such low-energy electrons may form ultra-low-electron-temperature plasma.

In other words, in the plasma generation apparatus (1) of the disclosed invention, primary plasma may be generated from the first gas in the first chamber (11), and an electron beam may be generated in the second chamber (12) from the primary plasma of the first chamber (11) that has passed through the grid unit (20).

Further, in the plasma generation apparatus (1) of the disclosed invention, an ultra-low-electron-temperature plasma including a specific radical may be generated from the second gas of the second chamber (12) by using energy of the generated electron beam.

Here, the specific radical may be defined as a radical active species required according to each process, and types of radical active species may be differently generated by adjusting the voltage of the grid unit (20).

The substrate (60) may be disposed below the second chamber (12) so that radicals included in the ultra-low-electron-temperature plasma are adsorbed thereon. Accordingly, radicals required for a process may be generated at high density around the substrate (60).

Accordingly, when energy of accelerated electrons is precisely controlled by adjusting the voltage of the grid unit (20) according to the disclosed invention, radical active species required for deposition can be selectively controlled. Details related thereto will be described below.

The plasma measuring instrument (70) may measure various parameters of plasma generated inside the chamber. In this specification, the term “parameter” may mean various chemical and physical characteristics related to plasma.

For example, the parameter may mean plasma density inside the chamber, ion density, electron density, electron temperature, and the like.

The electron energy probability function measuring instrument (80) may measure an electron-energy probability distribution inside the chamber.

Although the plasma measuring instrument (70) and the electron energy probability function measuring instrument (80) are separately illustrated in FIG. 4, the disclosed invention is not limited thereto, and they may of course be integrated into a single plasma-state measuring unit capable of measuring various parameters of plasma inside the chamber.

In addition, a method of generating high-density plasma inside the first chamber (11) is not limited to the above-described embodiment, and the first chamber (11) may generate high-density plasma with various configurations and structures.

For example, plasma generated in the first chamber (11) may be induced using various sources such as capacitive coupled plasma (CCP), inductively coupled plasma (ICP), an electron beam source, and microwave plasma.

Referring to FIG. 5, it can be confirmed that, in the plasma generation apparatus (1) according to the disclosed invention, electron-beam energy is formed linearly according to a grid voltage of the grid unit (20).

Accordingly, the plasma generation apparatus (1) according to the disclosed invention can precisely control energy of the electron beam applied to the second chamber (12) by adjusting the voltage of the grid unit (20).

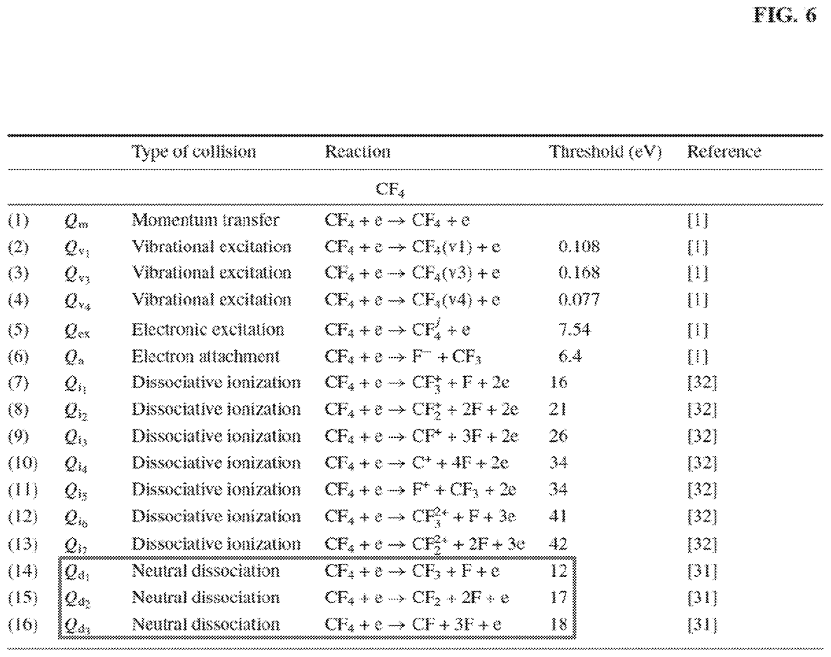

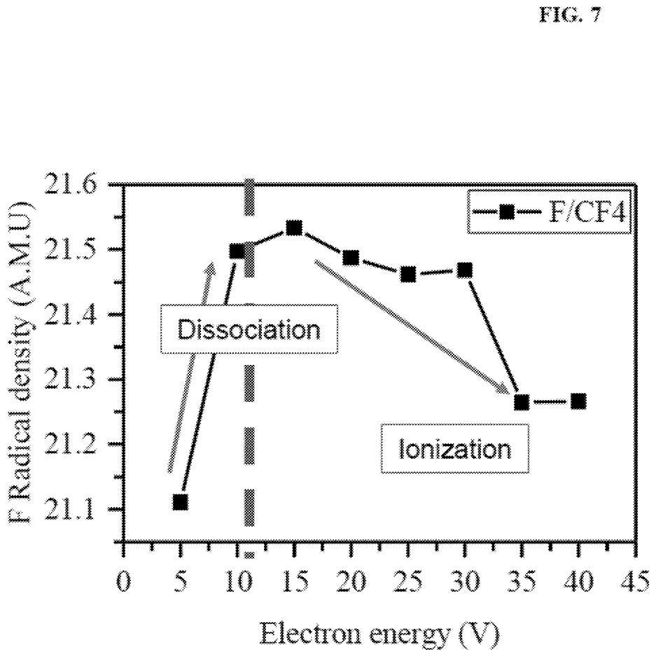

FIG. 6 is a view showing electron-beam energy required according to radical active species generated through dissociation reaction of CF4 molecules in the plasma generation apparatus of FIG. 4. FIG. 7 is a view showing radical density of F atoms according to electron-beam energy based on the graph shown in FIG. 6.

Referring to FIG. 6, it can be confirmed that electron-beam energies required for dissociation reactions of CF4 molecules are respectively 12 eV, 17 eV, and 18 eV.

Referring to FIG. 7, it can be confirmed that, as the electron-beam energy increases from 5 eV to 10 eV, radical density of F atoms gradually increases. Thereafter, as the electron-beam energy increases from 10 eV to 17 eV, the radical density of F atoms increases toward a maximum value.

Therefore, the disclosed invention has a technical effect in that unnecessary radical generation can be prevented by controlling energy of the electron beam according to a type of radical active species required for deposition on the substrate (60).

Further, because plasma formed in the second chamber (12) is ionized using the electron beam, electrons included in the second chamber (12) form a very low electron temperature, and such low-energy electrons can form ultra-low-electron-temperature plasma.

Therefore, the disclosed invention has a technical effect of controlling energy of the electron beam by controlling the voltage applied to the grid unit (20), and selectively generating target radical active species through selective dissociation in the ultra-low-electron-temperature plasma region.

In addition, the disclosed invention has a technical effect in that only active species required for thin-film formation are selectively generated and, due to low ion energy in the ultra-low-electron-temperature plasma, additional dissociation or ionization reactions of radicals do not occur, whereby process speed is improved and damage to the substrate (60) can be minimized.

Accordingly, the disclosed invention may be applied to an ALD process for deposition of a gate insulating film during a manufacturing process of a gate-all-around (GAA) structure transistor.

Further, in the plasma generation apparatus (1) according to the disclosed invention, the supply flow rate of the first gas in the first chamber (11) may be at least twice the supply flow rate of the second gas in the second chamber (12). Preferably, the supply flow rate of the first gas in the first chamber (11) may be ten times the supply flow rate of the second gas in the second chamber (12).

As described above, by setting the supply flow rate of the first gas in the first chamber (11) to be greater than the supply flow rate of the second gas in the second chamber (12), the disclosed invention can prevent plasma from back-flowing from the second chamber (12) to the first chamber (11), and accordingly can maintain radical density around the substrate (60) at a higher density.

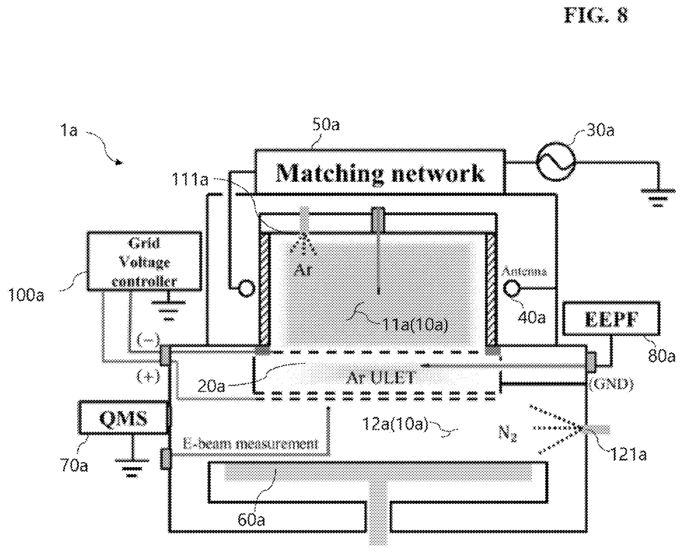

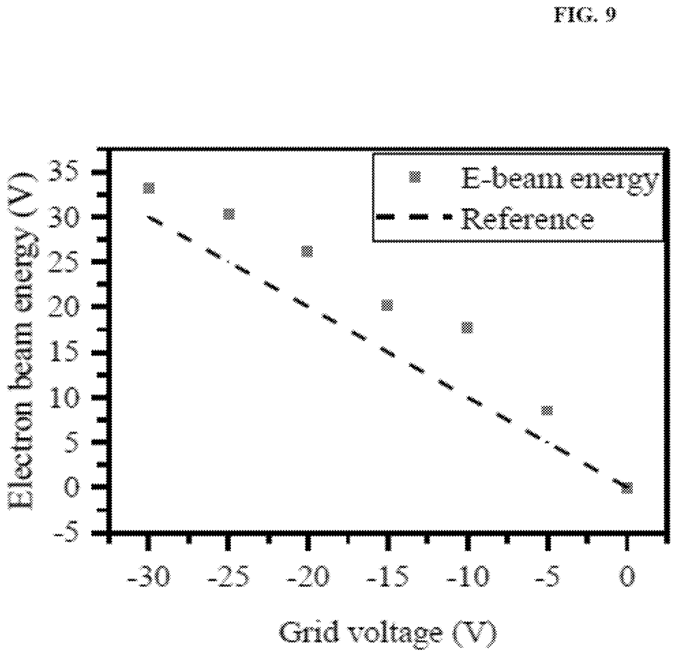

FIG. 8 is a view illustrating a plasma generation apparatus using an electron beam according to another embodiment of the disclosed invention. FIG. 9 is a view showing electron-beam energy generated according to grid voltage in the plasma generation apparatus of FIG. 8.

Referring to FIG. 8, a plasma generation apparatus (1a) using an electron beam according to the disclosed invention (hereinafter referred to as the “plasma generation apparatus (1a)”) may include a plurality of chambers (10a) serving as a main body that defines a space in which plasma is generated, a power source (30a), a plurality of antennas (40a) disposed at one side of the chamber to generate plasma, an impedance matching unit (50a) connected to the antennas (40a) to match impedance of the antennas (40a), a substrate (60a) on which a plasma process is performed, a plasma measuring instrument (70a) capable of measuring various parameters of plasma inside the chamber, and an electron energy probability function measuring instrument (80a) for measuring energy of electrons.

The plasma generation apparatus (1a) according to the disclosed invention may process the substrate (60a) disposed inside the chamber by using plasma. For example, the plasma generation apparatus (1a) may perform an etching process, a deposition process, an etch process, and an ion implantation process on the substrate (60a) through plasma.

Further, the plasma generation apparatus (1a) according to the disclosed invention may be defined as a plasma generation apparatus using various plasma generation sources, such as capacitive coupled plasma (CCP), inductively coupled plasma (ICP), an electron beam source, electron cyclotron resonance (ECR), microwave plasma, and helicon plasma.

The plurality of chambers (10a) of the plasma generation apparatus (1a) according to the disclosed invention may be provided as conductive material such as aluminum or stainless steel and may be configured in a grounded state.

The plurality of chambers (10a) may include a first chamber (11a) and a second chamber (12a).

The first chamber (11a) may be configured to define a space in which plasma is generated and to receive a first gas through a first gas inlet (111a).

More specifically, the first gas supplied into the first chamber (11a) may be converted into plasma by an induced electric field applied by the antenna (40a), which is connected to the power source (30a) and generates the induced electric field. Accordingly, the first chamber (11a) may define a space in which primary plasma is generated. Such primary plasma may be used as source plasma for forming an electron beam applied to the second chamber (12a), which will be described later.

In the plasma generation apparatus (1a) according to another embodiment of the disclosed invention, a plurality of antennas (40a) for generating plasma may be installed at a side portion of the first chamber (11a), and the plurality of antennas (40a) may be connected to the impedance matching unit (50a). The impedance matching unit (50a) is connected to the power source (30a) that supplies power to the plasma generation apparatus (1a), and the power source (30a) may be implemented as an RF power source or a DC power source.

Here, the first gas of the first chamber (11a) used in the plasma generation apparatus (1a) of the disclosed invention may be argon gas.

However, the first gas of the first chamber (11a) is not limited thereto and may be implemented to include any one of inert-gas-series gases.

The second chamber (12a) may provide a space in which the substrate (60a) is positioned and a process is performed. More specifically, the second chamber (12a) is disposed below the first chamber (11a) and may receive, through the second gas inlet (121a), a second gas to be used for processing the substrate (60a).

Here, the second gas inlet (121a) may be disposed between a lower layer of the grid unit (20a) and the substrate (60a) and closer to the grid unit (20a). In addition, the second gas inlet (121a) may be disposed at a side portion of the second chamber (12a) so as to supply the second gas to the second chamber (12a) without interfering with the grid unit (20a).

Further, the second chamber (12a) may be partitioned from the first chamber (11a) by the grid unit (20a) and may receive an electron beam generated from the primary plasma of the first chamber (11a) to generate secondary plasma. Such secondary plasma may be referred to as ultra-low-electron-temperature plasma.

The grid unit (20a) of the plasma generation apparatus (1a) according to the disclosed invention may be disposed between the first chamber (11a) and the second chamber (12a).

More specifically, the grid unit (20a) may be connected to a grid voltage controller (100a). For example, the grid voltage controller (100a) may apply a voltage to the grid unit (20a) so as to adjust sheath potential energy formed at the grid unit (20a).

In the plasma generation apparatus (1a) of the disclosed invention, sheath potential energy of the grid unit is one of important physical concepts mainly used for confining and controlling ionized particles (plasma ions).

Various types of grids may be used in the plasma generation apparatus according to the disclosed invention, and such grids may be used to control movement of ions in plasma and maintain the plasma stably. In addition, the grid unit (20a) may mainly confine and accelerate ions by using an electric field.

Sheath potential energy represents energy obtained by ions around the grid and is related to a voltage difference between the electric field and the grid. The sheath potential energy may be calculated as follows:

Sheath potential energy=voltage (V)×charge of ion (e)

In this region, sheath potential energy has a great influence on movement of ions, and characteristics and behavior of plasma may be determined according to how the value is adjusted. By adjusting the sheath potential energy, acceleration and confinement of ions become possible, thereby making it possible to control density, temperature, and stability of plasma.

Accordingly, a sheath voltage may be generated at the grid unit (20a) of the disclosed invention, and only high-energy electrons exceeding the sheath potential energy of the grid unit (20a) can move from the first chamber (11a) to the second chamber (12a).

Thereafter, electrons that have moved to the second chamber (12a) may be amplified into high-energy electrons. The high-energy electrons with amplified electron energy may ionize neutral gases present in the second chamber (12a).

In the plasma generation apparatus (1a) according to another embodiment of the disclosed invention, the neutral gas corresponding to the second gas of the second chamber (12a) may be implemented as N2 gas. That is, the first gas of the first chamber (11a) and the second gas of the second chamber (12a) may be different types of gases.

In addition, low-energy electrons generated through ionization in the second chamber (12a), together with electrons that came down from the first chamber (11a) to below the grid unit (20a) while gaining energy but lost energy by participating in ionization reactions, form a very low electron temperature, and such low-energy electrons may form ultra-low-electron-temperature plasma.

In other words, in the plasma generation apparatus (1a) of the disclosed invention, primary plasma may be generated from the first gas in the first chamber (11a), and an electron beam may be generated in the second chamber (12a) from the primary plasma of the first chamber (11a) that has passed through the grid unit (20a).

Further, in the plasma generation apparatus (1a) of the disclosed invention, an ultra-low-electron-temperature plasma including a specific radical may be generated from the second gas of the second chamber (12a) by using energy of the generated electron beam.

Here, the specific radical may be defined as a radical active species required according to each process, and types of radical active species may be differently generated by adjusting the voltage of the grid unit (20a).

The substrate (60a) may be disposed below the second chamber (12a) so that radicals included in the ultra-low-electron-temperature plasma are adsorbed thereon. Accordingly, radicals required for a process may be generated at high density around the substrate (60a).

Accordingly, when energy of accelerated electrons is precisely controlled by adjusting the voltage of the grid unit (20a) according to the disclosed invention, radical active species required for deposition can be selectively controlled. Details related thereto will be described below.

The plasma measuring instrument (70a) may measure various parameters of plasma generated inside the chamber. In this specification, the term “parameter” may mean various chemical and physical characteristics related to plasma.

For example, the parameter may mean plasma density inside the chamber, ion density, electron density, electron temperature, and the like.

The electron energy probability function measuring instrument (80a) may measure an electron-energy probability distribution inside the chamber.

Although the plasma measuring instrument (70a) and the electron energy probability function measuring instrument (80a) are separately illustrated in FIG. 8, the disclosed invention is not limited thereto, and they may of course be integrated into a single plasma-state measuring unit capable of measuring various parameters of plasma inside the chamber.

In addition, a method of generating high-density plasma inside the first chamber (11a) is not limited to the above-described embodiment, and the first chamber (11a) may generate high-density plasma with various configurations and structures.

For example, plasma generated in the first chamber (11a) may be induced using various sources such as capacitive coupled plasma (CCP), inductively coupled plasma (ICP), an electron beam source, and microwave plasma.

Referring to FIG. 9, it can be confirmed that, in the plasma generation apparatus (1a) according to the disclosed invention, electron-beam energy is formed linearly according to a grid voltage of the grid unit (20a).

Accordingly, the plasma generation apparatus (1a) according to the disclosed invention can precisely control energy of the electron beam applied to the second chamber (12a) by adjusting the voltage of the grid unit (20a).

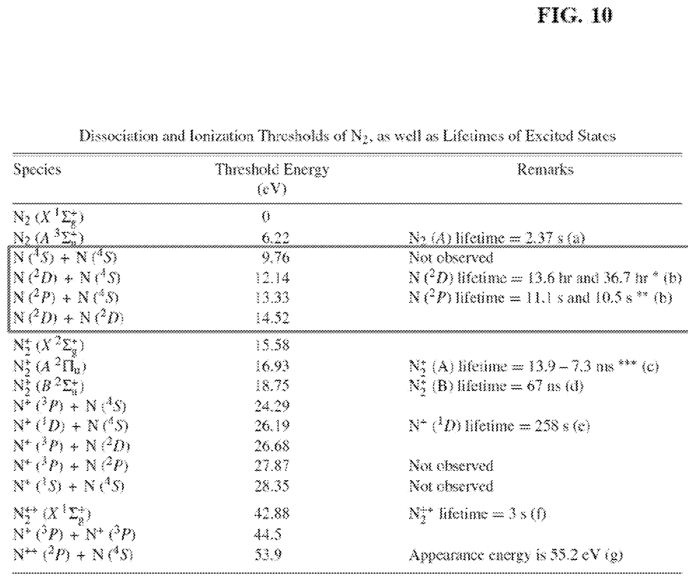

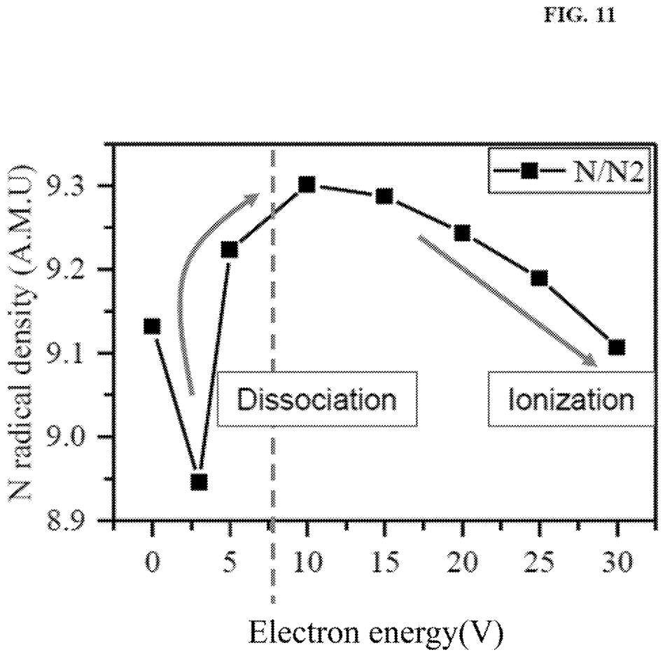

FIG. 10 is a view showing electron-beam energy required according to radical active species generated through dissociation reaction of N2 molecules in the plasma generation apparatus of FIG. 8. FIG. 11 is a view showing radical density of N atoms according to electron-beam energy based on the graph shown in FIG. 10.

Referring to FIG. 10, it can be confirmed that electron-beam energies required for dissociation reactions of N2 molecules are respectively 9.76 eV, 12.14 eV, 13.33 eV, and 14.52 eV.

Referring to FIG. 11, it can be confirmed that, as the electron-beam energy increases from 5 eV to 10 eV, radical density of N atoms gradually increases. Thereafter, as the electron-beam energy increases from 10 eV to 12 eV, the radical density of N atoms increases toward a maximum value.

Therefore, the disclosed invention has a technical effect in that unnecessary radical generation can be prevented by controlling energy of the electron beam according to a type of radical active species required for deposition on the substrate (60a).

Further, because plasma formed in the second chamber (12a) is ionized using the electron beam, electrons included in the second chamber (12a) form a very low electron temperature, and such low-energy electrons can form ultra-low-electron-temperature plasma.

Therefore, the disclosed invention has a technical effect of controlling energy of the electron beam by controlling the voltage applied to the grid unit (20a), and selectively generating target radical active species through selective dissociation in the ultra-low-electron-temperature plasma region.

In addition, the disclosed invention has a technical effect in that only active species required for thin-film formation are selectively generated and, due to low ion energy in the ultra-low-electron-temperature plasma, additional dissociation or ionization reactions of radicals do not occur, whereby process speed is improved and damage to the substrate (60a) can be minimized.

Accordingly, the disclosed invention may be applied to an ALD process for deposition of a gate insulating film during a manufacturing process of a gate-all-around (GAA) structure transistor.

Further, in the plasma generation apparatus (1a) according to the disclosed invention, the supply flow rate of the first gas in the first chamber (11a) may be at least twice the supply flow rate of the second gas in the second chamber (12a). Preferably, the supply flow rate of the first gas in the first chamber (11a) may be ten times the supply flow rate of the second gas in the second chamber (12a).

As described above, by setting the supply flow rate of the first gas in the first chamber (11a) to be greater than the supply flow rate of the second gas in the second chamber (12a), the disclosed invention can prevent plasma from back-flowing from the second chamber (12a) to the first chamber (11a), and accordingly can maintain radical density around the substrate (60a) at a higher density.

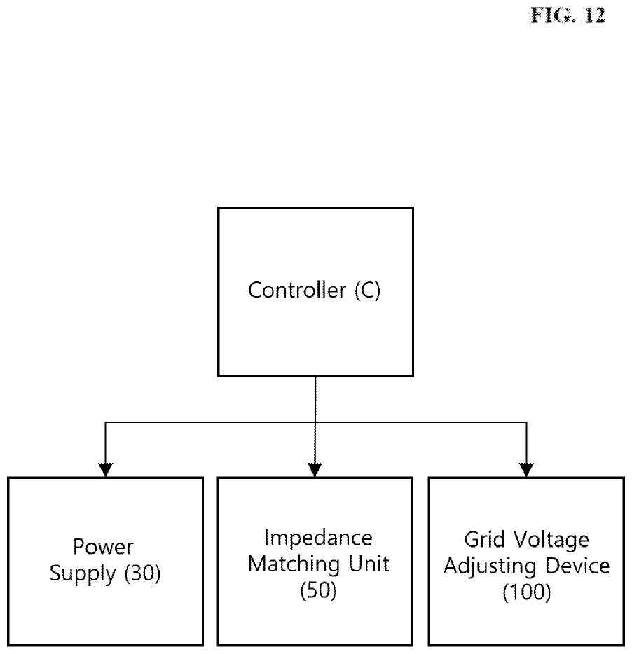

FIG. 12 is a view illustrating a partial configuration of the plasma generation apparatus according to an embodiment of the disclosed invention.

Referring to FIG. 12, the controller (C) of the plasma generation apparatus (1, 1a) according to the disclosed invention may control various components of the plasma generation apparatus (1, 1a). Specifically, the controller (C) may control the power source (30, 30a) that applies a voltage to the plasma generation apparatus (1, 1a), thereby controlling magnitude, phase, and the like of the voltage applied to the plasma generation apparatus (1, 1a).

In addition, the controller (C) may adjust magnitude of impedance of the impedance matching unit (50, 50a) so as to control an amount or density of plasma generated by the plasma generation apparatus (1, 1a).

In addition, the controller (C) according to the disclosed invention may adjust the voltage applied by the grid voltage controller (100, 100a) to the grid unit (20, 20a) according to a type of radical to be generated from the second gas of the second chamber (12, 12a).

More specifically, the controller (C) may control the grid voltage controller (100, 100a) so as to adjust the voltage applied by the grid voltage controller (100, 100a) to the grid unit (20, 20a), and accordingly may adjust energy of the electron beam accelerated after passing through the grid unit (20, 20a).

In other words, the controller (C) may adjust energy of an electron beam generated from plasma present inside the first chamber (11, 11a), and accordingly may selectively generate active species of radicals generated in the second chamber (12, 12a).

The controller (C) may be implemented as a processor, a controller, an arithmetic logic unit (ALU), a digital signal processor, a microcomputer, an FPA (field programmable array), a PLU (programmable logic unit), a microprocessor, or a device capable of executing and responding to instructions.

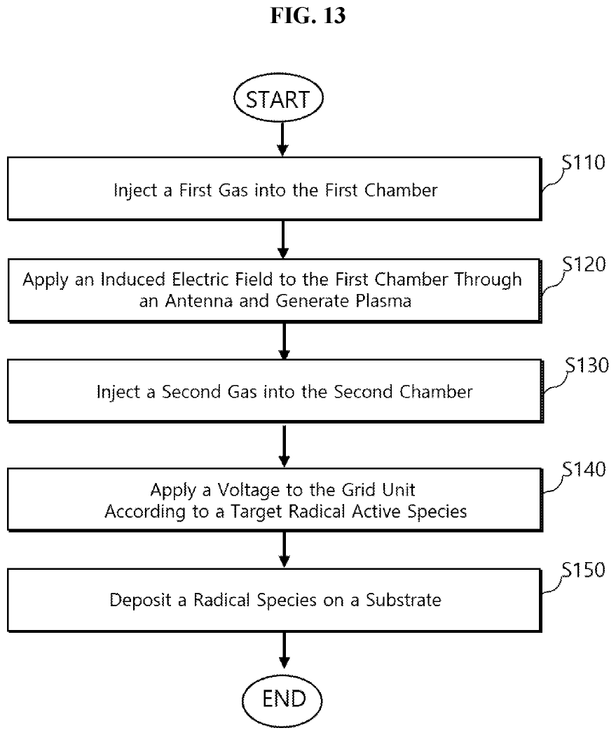

FIG. 13 is a view illustrating a plasma generation method according to an embodiment of the disclosed invention.

Referring to FIG. 13, the plasma generation method according to an embodiment of the disclosed invention may include introducing a first gas into a first chamber (11, 11a) (S110).

More specifically, the first gas may be supplied to the first chamber (11, 11a) through the first gas inlet (111, 111a) of the first chamber (11, 11a). Here, the first gas may be argon gas.

Further, the plasma generation method according to an embodiment of the disclosed invention may include applying an induced electric field through the antenna (40, 40a) disposed at one side of the first chamber (11, 11a), and generating high-density plasma from the first gas using the applied induced electric field (S120).

Further, the plasma generation method according to an embodiment of the disclosed invention may include introducing a second gas into a second chamber (12, 12a) disposed below the first chamber (11, 11a) (S130).

More specifically, a supply flow rate of the first gas supplied to the first chamber (11, 11a) may be at least twice a supply flow rate of the second gas supplied to the second chamber (12, 12a).

More preferably, the supply flow rate of the first gas supplied to the first chamber (11, 11a) may be ten times the supply flow rate of the second gas supplied to the second chamber (12, 12a).

Further, the plasma generation method according to an embodiment of the disclosed invention may include applying a voltage to the grid unit (20, 20a) disposed between the first chamber (11, 11a) and the second chamber (12, 12a) (S140).

More specifically, the applying of the voltage to the grid unit (20, 20a) (S140) may further include adjusting, by the controller (C), the voltage applied to the grid unit (20, 20a) according to a type of radical to be generated from the second gas of the second chamber (12, 12a).

Further, the plasma generation method according to an embodiment of the disclosed invention may further include generating an electron beam in the second chamber (12, 12a) from plasma through the grid unit (20, 20a).

Further, the plasma generation method according to an embodiment of the disclosed invention may include depositing radicals on a substrate (60, 60a) disposed below the second chamber (12, 12a) (S150).

The plasma generation apparatus and method using an electron beam according to an embodiment of the disclosed invention have an advantage in that gases are respectively introduced into the first chamber and the second chamber, primary plasma is generated in the first chamber, an electron beam is generated from the primary plasma, and an ultra-low-electron-temperature plasma including radicals can be generated in the second chamber through the electron beam, so that radicals required for deposition can be obtained at high density.

In addition, an apparatus and method for generating plasma using an electron beam according to an embodiment have an advantage in that radical active species required for deposition can be selectively generated by controlling, through the grid unit, energy of the electron beam required for radical generation.

In addition, an apparatus and method for generating plasma using an electron beam according to an embodiment have an advantage in that additional decomposition of radicals used for deposition can be minimized, thereby securing high process yield.

In addition, an apparatus and method for generating plasma using an electron beam according to an embodiment have an advantage in that, without changing the structure of existing equipment, radicals can be generated by using the electron beam and the ultra-low-electron-temperature plasma so as to minimize substrate damage, thereby enabling a high-purity deposition process.

Effects of the present invention are not limited to the above-mentioned technical tasks, and other effects not mentioned herein will be clearly understood by those skilled in the art from the following description.

The apparatus described above may be implemented by hardware components, software components, and/or a combination of hardware components and software components. For example, the apparatus and components described in the embodiments may be implemented by using one or more general-purpose computers or special-purpose computers, such as a processor, a controller, an arithmetic logic unit (ALU), a digital signal processor, a microcomputer, an FPA (field programmable array), a PLU (programmable logic unit), a microprocessor, or any other device capable of executing and responding to instructions. The processing device may execute an operating system (OS) and one or more software applications executed on the operating system. In addition, the processing device may access, store, manipulate, process, and generate data in response to execution of software. For convenience of understanding, one processing device may be described as being used, but a person having ordinary skill in the art will appreciate that the processing device may include a plurality of processing elements and/or a plurality of types of processing elements. For example, the processing device may include a plurality of processors or one processor and one controller. Other processing configurations, such as a parallel processor, are also possible.

The software may include a computer program, code, instructions, or one or more combinations thereof, and may configure the processing device to operate as desired or may instruct the processing device independently or collectively. The software and/or data may be embodied in any type of machine, component, physical device, virtual equipment, computer storage medium, or device, in order to be interpreted by the processing device or to provide instructions or data to the processing device. The software may be distributed over computer systems connected by a network so as to be stored or executed in a distributed manner. The software and data may be stored in one or more computer-readable recording media.

A method according to an embodiment may be implemented in the form of program instructions that can be executed by various computer means and may be recorded on a computer-readable medium. Examples of the computer-readable recording medium include magnetic media such as a hard disk, floppy disk, and magnetic tape; optical recording media such as a CD-ROM and a DVD; magneto-optical media such as a floptical disk; and hardware devices specially configured to store and execute program instructions, such as ROM, RAM, and flash memory. Examples of the program instructions include machine language code generated by a compiler as well as high-level language code executable by a computer using an interpreter or the like.

Although embodiments have been described above with reference to limited embodiments and drawings, various modifications and variations can be made by those skilled in the art from the above description. For example, appropriate results may be achieved even when the described techniques are performed in an order different from the described method and/or when components of the described systems, structures, apparatuses, circuits, and the like are combined or coupled in a form different from the described method, or are replaced or substituted by other components or equivalents. Accordingly, other implementations, other embodiments, and equivalents to the claims also fall within the scope of the claims set forth below.

What is claimed is:

1. A plasma generation apparatus using an electron beam, comprising:
a first chamber configured to define a space in which plasma is generated and to receive a first gas through a first gas inlet;
a second chamber disposed below the first chamber and configured to receive a second gas through a second gas inlet; and
a grid unit disposed between the first chamber and the second chamber.

2. The plasma generation apparatus of claim 1, further comprising:
a grid voltage controller configured to apply a voltage to the grid unit so as to adjust sheath potential energy formed at the grid unit.

3. The plasma generation apparatus of claim 2, further comprising:
a controller configured to adjust the voltage applied by the grid voltage controller according to a type of radical to be generated from the second gas in the second chamber.

4. The plasma generation apparatus of claim 1,
wherein a supply flow rate of the first gas is at least twice a supply flow rate of the second gas.

5. The plasma generation apparatus of claim 1,
wherein plasma is generated from the first gas in the first chamber, and an electron beam is generated in the second chamber from the plasma that has passed through the grid unit.

6. The plasma generation apparatus of claim 5,
wherein an ultra-low-electron-temperature plasma including a specific radical is generated from the second gas in the second chamber by using energy of the electron beam.

7. The plasma generation apparatus of claim 6, further comprising:
a substrate disposed below the second chamber so that the specific radical included in the ultra-low-electron-temperature plasma is adsorbed thereon.

8. The plasma generation apparatus of claim 1,
wherein the second gas inlet is disposed between a lower layer of the grid unit and a substrate and is positioned closer to the grid unit.

9. The plasma generation apparatus of claim 1,
wherein the first gas and the second gas are different types of gases.

10. A plasma generation method using an electron beam, the method comprising:
introducing a first gas into a first chamber;
applying an induced electric field through an antenna disposed at one side of the first chamber, and generating high-density plasma from the first gas using the applied induced electric field;
introducing a second gas into a second chamber disposed below the first chamber; and
applying a voltage to a grid unit disposed between the first chamber and the second chamber.

11. The plasma generation method of claim 10, wherein the applying of the voltage to the grid unit further comprises:
adjusting, by a controller, the voltage applied to the grid unit according to a type of radical to be generated from the second gas in the second chamber.

12. The plasma generation method of claim 10, further comprising:
generating an electron beam in the second chamber from plasma through the grid unit.

13. The plasma generation method of claim 10,
wherein a supply flow rate of the first gas is at least twice a supply flow rate of the second gas.

14. The plasma generation method of claim 11, further comprising:
depositing a radical on a substrate disposed below the second chamber.

15. A plasma generation apparatus using an electron beam, comprising:
a first chamber configured to define a space in which plasma is generated and to receive a first gas through a first gas inlet;
an antenna connected to a power source, disposed at one side of the first chamber, and configured to generate an induced electric field and supply the induced electric field to the first chamber;
a second chamber disposed below the first chamber and configured to receive a second gas through a second gas inlet; and
a grid unit disposed between the first chamber and the second chamber and configured to allow the first gas to pass into the second chamber,
wherein an ultra-low-electron-temperature plasma including a specific radical is generated from the second gas in the second chamber by using energy of an electron beam generated from the first gas through the grid unit.
